(19) United States
(12) Patent Application Publication
(10) Pub. No.: US 2026/0082619 A1
(43) Pub. Date: Mar. 19, 2026

(54) HIGH-VOLTAGE SEMICONDUCTOR DEVICE

(71) Applicant: UNITED MICROELECTRONICS CORP., Hsin-Chu City (TW)

(72) Inventors: Shin-Hung Li, Nantou County (TW); Jhen-Jia Yang, Tainan City (TW); Yueh-Chang Lin, Tainan City (TW); Shan-Shi Huang, Hsinchu City (TW); Ming-Hua Tsai, Tainan City (TW)

(73) Assignee: UNITED MICROELECTRONICS CORP., Hsin-Chu City (TW)

(21) Appl. No.: 18/929,575

(22) Filed: Oct. 28, 2024

(30) Foreign Application Priority Data
Sep. 19, 2024 (TW) 113135472

(51) Int. Cl. H01L 29/78; H01L 29/06; H01L 29/10; H01L 29/423; H01L 29/49

(52) U.S. Cl. CPC H10D 30/65; H10D 62/125; H10D 62/307; H10D 64/512; H10D 64/668

(57) ABSTRACT

A high-voltage semiconductor device includes a semiconductor substrate, a gate structure, a first drift region, a second drift region, and a gate contact structure. The gate structure is disposed on the semiconductor substrate. The first drift region and the second drift region are disposed in the semiconductor substrate. A part of the first drift region and a part of the second drift region are located at two opposite sides of the gate structure in a horizontal direction, respectively. The first drift region is partly located under the gate structure in a vertical direction, and the semiconductor substrate includes a semiconductor region sandwiched between the first drift region and the second drift region in the horizontal direction. The gate contact structure is disposed on and electrically connected with the gate structure, and the gate contact structure is located directly above the semiconductor region in the vertical direction.

### BACKGROUND OF THE INVENTION

### 1. Field of the Invention

The present invention relates to a high-voltage semiconductor device, and more particularly, to a high-voltage semiconductor device including a drift region.

### 2. Description of the Prior Art

Double-diffused MOS (DMOS) transistor devices have drawn much attention in power devices having high voltage capability. The conventional DMOS transistor devices are categorized into vertical double-diffused MOS (VDMOS) transistor device and lateral double-diffused MOS (LDMOS) transistor device. Having advantage of higher operational bandwidth, higher operational efficiency, and convenience to be integrated with other integrated circuit due to its planar structure, LDMOS transistor devices are prevalently used in high operation voltage environment such as CPU power supply, power management system, AC/DC converter, and high-power or high frequency band power amplifier. The essential feature of LDMOS transistor device is a lateral-diffused drift region with low doping concentration and large area. The drift region is used to alleviate the high voltage between the drain and the source, and therefore LDMOS transistor device can have higher breakdown voltage. However, as the requirements of related products become higher and higher, how to improve the electrical performance and/or the distribution density of high-voltage semiconductor units through design modifications in structure and/or process is still a continuous issue for those in the relevant fields.

### SUMMARY OF THE INVENTION

A high-voltage semiconductor device is provided in the present invention. A gate contact structure is disposed directly above a semiconductor region sandwiched between two drift regions for reducing an area occupied by the high-voltage semiconductor device, and a distribution density of the high-voltage semiconductor devices may be relatively increased accordingly.

According to an embodiment of the present invention, a high-voltage semiconductor device is provided. The high-voltage semiconductor device includes a semiconductor substrate, a gate structure, a first drift region, a second drift region, and a gate contact structure. The gate structure is disposed on the semiconductor substrate. The first drift region and the second drift region are disposed in the semiconductor substrate. A part of the first drift region and a part of the second drift region are located at two opposite sides of the gate structure in a horizontal direction, respectively. The first drift region is partly located under the gate structure in a vertical direction, and the semiconductor substrate includes a semiconductor region sandwiched between the first drift region and the second drift region in the horizontal direction. The gate contact structure is disposed on and electrically connected with the gate structure, and the gate contact structure is located directly above the semiconductor region in the vertical direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a high-voltage semiconductor device according to a first embodiment of the present invention.

FIG. 2 is a schematic drawing illustrating layout design of the high-voltage semiconductor device according to the first embodiment of the present invention.

FIG. 3 is a schematic drawing illustrating a high-voltage semiconductor device according to a second embodiment of the present invention.

FIG. 4 is a schematic drawing illustrating layout design of the high-voltage semiconductor device according to the second embodiment of the present invention.

FIG. 5 is a schematic drawing illustrating a high-voltage semiconductor device according to a third embodiment of the present invention.

FIG. 6 is a schematic drawing illustrating layout design of the high-voltage semiconductor device according to the third embodiment of the present invention.

FIG. 7 is a schematic drawing illustrating a high-voltage semiconductor device according to a fourth embodiment of the present invention.

FIG. 8 is a schematic drawing illustrating layout design of the high-voltage semiconductor device according to the fourth embodiment of the present invention.

FIG. 9 is a schematic drawing illustrating a high-voltage semiconductor device according to a fifth embodiment of the present invention.

FIG. 10 is a schematic drawing illustrating a high-voltage semiconductor device according to a sixth embodiment of the present invention.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

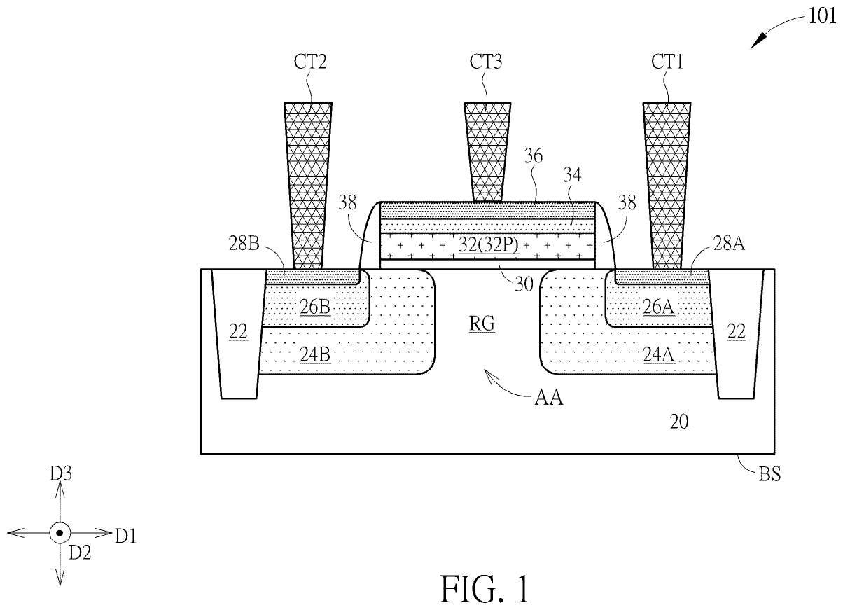

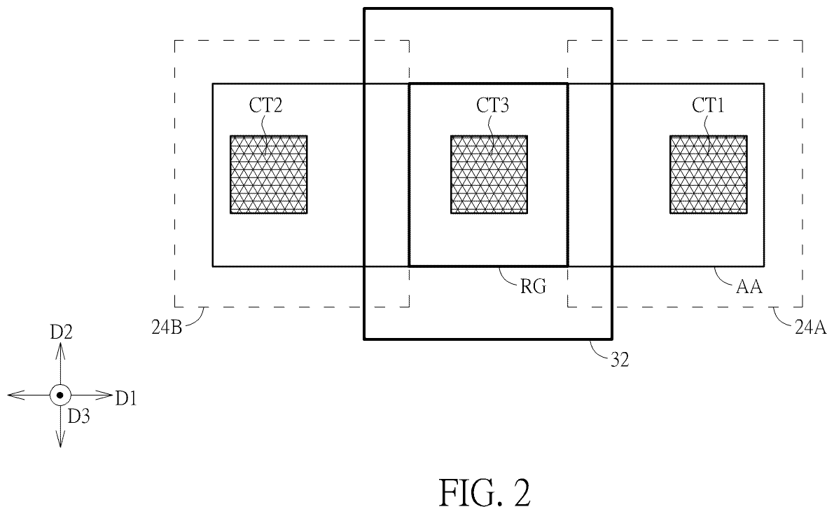

Please refer to FIG. 1 and FIG. 2. FIG. 1 is a schematic drawing illustrating a high-voltage semiconductor device 101 according to a first embodiment of the present invention, and FIG. 2 is a schematic drawing illustrating layout design of the high-voltage semiconductor device in this embodiment. In some embodiments, FIG. 2 may be regarded as a top view schematic drawing of the high-voltage semiconductor device 101, and some components are not illustrated in FIG. 2. As shown in FIG. 1 and FIG. 2, the high-voltage semiconductor device 101 includes a semiconductor substrate 20, a gate structure 32, a first drift region 24A, a second drift region 24B, and a gate contact structure CT3. The gate structure 32 is disposed on the semiconductor substrate 20. The first drift region 24A and the second drift region 24B are disposed in the semiconductor substrate 20. A part of the first drift region 24A and a part of the second drift region 24B are located at two opposite sides of the gate structure 32 in a horizontal direction (such as a horizontal direction D1), respectively. The first drift region 24A is partly located under the gate structure 32 in a vertical direction D3, and the semiconductor substrate 20 includes a semiconductor region RG sandwiched between the first drift region 24A and the second drift region 24B in the horizontal direction D1. The gate contact structure CT3 is disposed on and electrically connected with the gate structure 32, and the gate contact structure CT3 is located directly above the semiconductor region RG in the vertical direction D3. In other words, at least a part of the gate structure 32 may be sandwiched between the gate contact structure CT3 and the semiconductor region RG in the vertical direction D3. By disposing the gate contact structure CT3 directly above the semiconductor region RG sandwiched between the two drift regions, there is no need to increase the size of the gate structure in order to be connected with the gate contact structure CT3. Therefore, the area occupied by the high-voltage semiconductor device may be relatively reduced, and the distribution density of the high-voltage semiconductor devices (such as a number of the high-voltage semiconductor devices disposed within a unit area of a substrate, but not limited thereto) may be increased accordingly.

Specifically, in some embodiments, the semiconductor substrate 20 may include a silicon substrate, an epitaxial silicon substrate, a silicon germanium substrate, a silicon carbide substrate, a silicon-on-insulator (SOI) substrate, or a substrate made of other suitable semiconductor materials. The vertical direction D3 may be regarded as a thickness direction of the semiconductor substrate 20. The semiconductor substrate 20 may have a top surface and a bottom surface BS opposite to the top surface in the vertical direction D3, and the gate structure 32 and the gate contact structure CT3 may be disposed at the side of the top surface. A horizontal direction substantially orthogonal to the vertical direction D3 (such as the horizontal direction D1 and a horizontal direction D2) may be substantially parallel with the top surface and/or the bottom surface BS of the semiconductor substrate 20, but not limited thereto. Additionally, in this description, a distance between the bottom surface BS of the semiconductor substrate 20 and a relatively higher location and/or a relatively higher part in the vertical direction D3 may be greater than a distance between the bottom surface BS of the semiconductor substrate 20 and a relatively lower location and/or a relatively lower part in the vertical direction D3. The bottom or a lower portion of each component may be closer to the bottom surface BS of the semiconductor substrate 20 in the vertical direction D3 than the top or upper portion of this component, but not limited thereto. It is worth noting that, in this description, a top surface of a specific component may include the topmost surface of this component in the vertical direction D3, and a bottom surface of a specific component may include the bottommost surface of this component in the vertical direction D3, but not limited thereto. Additionally, in this description, the condition that a certain component is disposed between two other components in a specific direction may include but is not limited to a condition that the certain component is sandwiched between the two other components in the specific direction.

As shown in FIG. 1 and FIG. 2, in some embodiments, the high-voltage semiconductor device 101 may further include an isolation structure 22, a first source/drain doped region 26A, and a second source/drain doped region 26B. The isolation structure 22 is disposed in the semiconductor substrate 20 for defining one or a plurality of active regions (such as an active region AA), and the active region AA may be surrounded by the isolation structure 22 in the horizontal directions. The isolation structure 22 may include a single layer or multiple layers of insulation materials, such as an oxide insulation material or other suitable insolation materials, and the isolation structure 22 may be regarded as a shallow trench isolation (STI) structure, but not limited thereto. The first drift region 24A and the second drift region 24B may be disposed in the active region AA, and the semiconductor region RG may be regarded as a part of the active region AA. It is worth noting that, the regions marked as the first drift region 24A and the second drift region 24B in FIG. 2 are regions of openings in a mask pattern for forming the first drift region 24A and the second drift region 24B, and the first drift region 24A and the second drift region 24B are not formed outside the active region AA actually. In addition, the semiconductor region RG and the active region AA may be regarded as a portion of the semiconductor substrate 20 and include the material composition of the semiconductor substrate 20. In some embodiments, a doped well region (not illustrated) may be formed in the semiconductor substrate 20, and the semiconductor region RG and the active region AA may also be regarded as a portion of this doped well region and include the corresponding dopants, but not limited thereto. Additionally, in some embodiments, the semiconductor region RG sandwiched between the first drift region 24A and the second drift region 24B in the horizontal direction D1 and located directly under the gate structure 32 in the vertical direction D3 may also be regarded as a channel region of the high-voltage semiconductor device 101, but not limited thereto.

The first source/drain doped region 26A and the second source/drain doped region 26B may be disposed in the semiconductor substrate 20 and located in the first drift region 24A and the second drift region 24B, respectively. The first drift region 24A, the second drift region 24B, the first source/drain doped region 26A, and the second source/drain doped region 26B may be doped regions formed by performing corresponding doping processes (such as implantation processes) to the semiconductor substrate 20. In some embodiments, the first drift region 24A and the second drift region 24B may have the same conductivity type, the first source/drain doped region 26A and the second source/drain doped region 26B may have the same conductivity type, and the conductivity type of the first source/drain doped region 26A and the second source/drain doped region 26B may be identical to the conductivity type of the first drift region 24A and the second drift region 24B. For example, when the first drift region 24A and the second drift region 24B are p-type doped drift regions (such as p-type lightly doped regions, but not limited thereto), the first source/drain doped region 26A and the second source/drain doped region 26B may be p-type heavily doped regions. When the first drift region 24A and the second drift region 24B are n-type doped drift regions (such as n-type lightly doped regions, but not limited thereto), the first source/drain doped region 26A and the second source/drain doped region 26B may be n-type heavily doped regions. In other words, the dopant concentration of the first source/drain doped region 26A and the second source/drain doped region 26B may be higher than that of the first drift region 24A and the second drift region 24B. In addition, the conductivity type of the semiconductor region RG may be complementary to the conductivity type of the first drift region 24A and the second drift region 24B.

In some embodiments, the high-voltage semiconductor device 101 may further include a gate dielectric layer 30 and a spacer structure 38. The gate dielectric layer 30 may be disposed between the gate structure 32 and the semiconductor substrate 20, and the spacer structure 38 may be disposed on a sidewall of the gate dielectric layer 30 and a sidewall of the gate structure 32. The gate dielectric layer 30 may include an oxide dielectric material (such as silicon oxide, but not limited thereto), a high dielectric constant (high-k) dielectric material, or other suitable dielectric materials, and the spacer structure 38 may include a single layer or multiple layers of dielectric materials, such as silicon nitride, silicon oxynitride, or other suitable dielectric materials. In addition, the gate structure 32 may include a non-metallic electrically conductive material (such as doped polysilicon) or a metallic electrically conductive material, such as a metal gate structure composed of a work function layer and a low resistivity layer stacked with one another, but not limited thereto. For example, in some embodiments, the gate structure 32 may be a non-metallic gate structure 32P, the non-metallic gate structure 32P may include polysilicon or other suitable non-metallic electrically conductive materials. When the gate structure 32 is the non-metallic gate structure 32P, the high-voltage semiconductor device 101 may further include a doped region 34 and a silicide layer 36. The doped region 34 may be disposed in the gate structure 32, and a part of the doped region 34 may be sandwiched between the gate contact structure CT3 and the semiconductor region RG in the vertical direction D3 and/or sandwiched between the gate contact structure CT3 and the gate dielectric layer 30 in the vertical direction D3. At least a part of the silicide layer 36 may be disposed in the doped region 34, and the gate contact structure CT3 may be disposed above the silicide layer 36 in the vertical direction D3. The gate contact structure CT3 may directly contact the silicide layer 36, and the gate contact structure CT3 may be electrically connected with the gate structure 32 via the silicide layer 36 and the doped region 34. In some embodiments, the doping condition and/or the conductivity type of the doped region 34 may be identical to that of the first source/drain doped region 26A and the second source/drain doped region 26B, but not limited thereto. Additionally, in some embodiments, the spacer structure 38 may be disposed on the sidewall of the silicide layer 36 and the sidewall of the doped region 34 and directly contact the silicide layer 36 and the doped region 34, and at least a part of the gate structure 32 may be sandwiched between the doped region 34 and the gate dielectric layer 30 in the vertical direction D3, but not limited thereto.

In some embodiments, the high-voltage semiconductor device 101 may further include a first source/drain contact structure CT1, a second source/drain contact structure CT2, a silicide layer 28A, and a silicide layer 28B. The first source/drain contact structure CT1 is disposed on and electrically connected with the first source/drain doped region 26A, and the second source/drain contact structure CT2 is disposed on and electrically connected with the second source/drain doped region 26B. At least a part of the silicide layer 28A may be disposed in the first source/drain doped region 26A, and at least a part of the silicide layer 28B may be disposed in the second source/drain doped region 26B. The first source/drain contact structure CT1 may directly contact the silicide layer 28A and may be electrically connected with the first source/drain doped region 26A via the silicide layer 28A, and the second source/drain contact structure CT2 may directly contact the silicide layer 28B and may be electrically connected with the second source/drain doped region 26B via the silicide layer 28B. The silicide layer 28A, the silicide layer 28B, and the silicide layer 36 may respectively include cobalt-silicide, nickel-silicide, or other suitable metal silicide. The gate contact structure CT3, the first source/drain contact structure CT1, and the second source/drain contact structure CT2 may respectively include a barrier layer and an electrically conductive material disposed on this barrier. The barrier layer may include titanium, titanium nitride, tantalum, tantalum nitride, or other suitable electrically conductive barrier materials. The electrically conductive material may include tungsten, copper, aluminum, titanium aluminide, cobalt tungsten phosphide, or other suitable electrically conductive materials with relatively low electrical resistivity. In some embodiments, the gate contact structure CT3 may be sandwiched between the first source/drain contact structure CT1 and the second source/drain contact structure CT2 in the horizontal direction D1, and a distance between the gate contact structure CT3 and the first source/drain contact structure CT1 in the horizontal direction D1 may be substantially equal to a distance between the gate contact structure CT3 and the second source/drain contact structure CT2 in the horizontal direction D1, but not limited thereto.

In some embodiments, the active region AA may be elongated in the horizontal direction D1 substantially, the gate structure 32 may be elongated in the horizontal direction D2 substantially, and the horizontal direction D2 may be substantially orthogonal to the horizontal direction D1, but not limited thereto. When the high-voltage semiconductor device 101 is viewed in the vertical direction D3 (such as the condition shown in FIG. 2, but not limited thereto), the gate contact structure CT3 does not overlap the first drift region 24A and the gate contact structure CT3 does not overlap the second drift region 24B. In some embodiments, the first drift region 24A and the second drift region 24B may be partly located under the gate structure 32 in the vertical direction D3, the two source/drain doped regions may be a source region and a drain region (for instance, the first source/drain doped region 26A may be a drain region while the second source/drain doped region 26B is a source region, or the first source/drain doped region 26A may be a source region while the second source/drain doped region 26B is a drain region), and the high-voltage semiconductor device 101 may be regarded as a double-diffused drain MOSFET (DDDMOS) structure, but not limited thereto. In some embodiments, the high-voltage semiconductor device 101 may be regarded as a symmetric DDDMOS structure, and a length of the first drift region 24A disposed under the gate structure 32 in the horizontal direction D1 may be substantially equal to a length of the second drift region 24B disposed under the gate structure 32 in the horizontal direction D1. A distance between the first source/drain doped region 26A and the gate structure 32 in the horizontal direction D1 may be substantially equal to a distance between the second source/drain doped region 26B and the gate structure 32 in the horizontal direction D1. A distance between the silicide layer 28A and the gate structure 32 in the horizontal direction D1 may be substantially equal to a distance between the silicide layer 28B and the gate structure 32 in the horizontal direction D1. A distance between the gate contact structure CT3 and the first drift region 24A in the horizontal direction D1 may be substantially equal to a distance between the gate contact structure CT3 and the second drift region 24B in the horizontal direction D1.

The following description will detail the different embodiments of the present invention. To simplify the description, the following description will detail the dissimilarities among different embodiments and the identical features will not be redundantly described. In addition, identical components in each of the following embodiments are marked with identical symbols for making it easier to understand the differences between the embodiments.

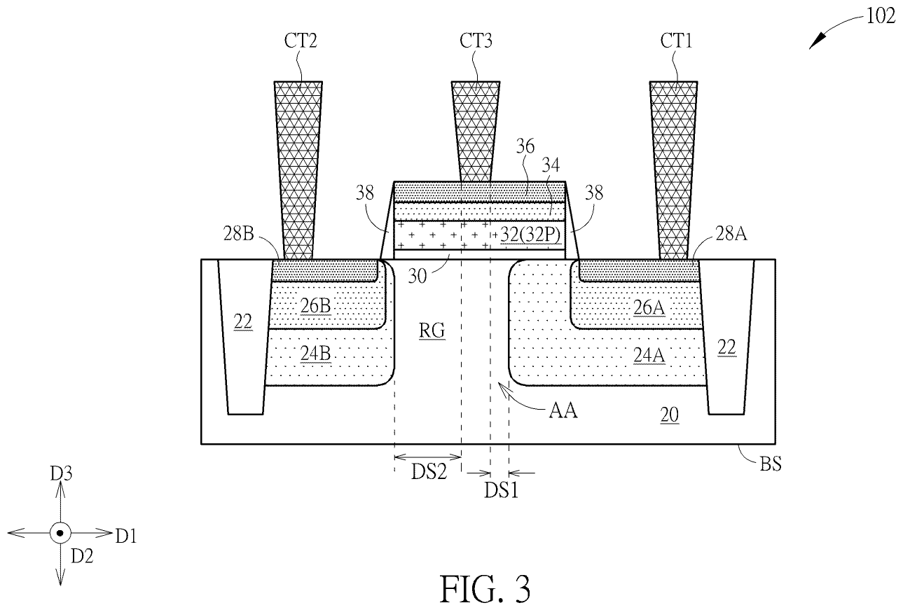

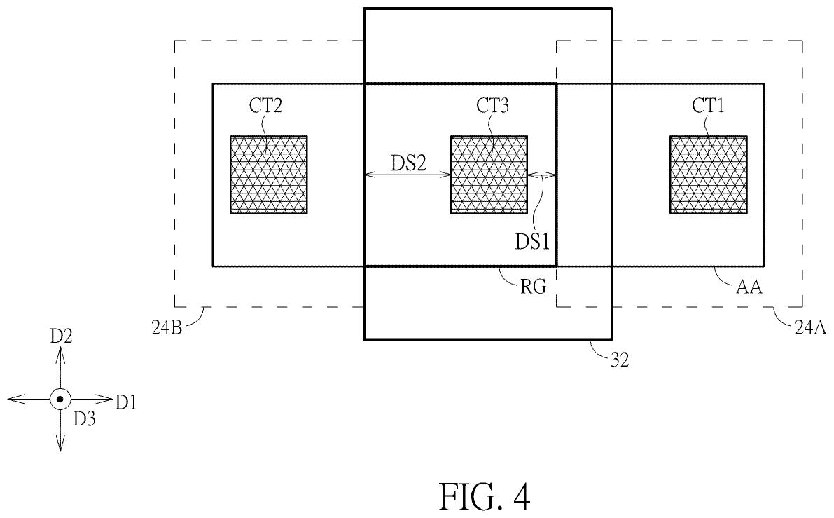

Please refer to FIG. 3 and FIG. 4. FIG. 3 is a schematic drawing illustrating a high-voltage semiconductor device 102 according to a second embodiment of the present invention, and FIG. 4 is a schematic drawing illustrating layout design of the high-voltage semiconductor device in this embodiment. In some embodiments, FIG. 4 may be regarded as a top view schematic drawing of the high-voltage semiconductor device 102, and some components are not illustrated in FIG. 4. As shown in FIG. 3 and FIG. 4, in the high-voltage semiconductor device 102, the first drift region 24A may be partly located under the gate structure 32 in the vertical direction D3, the second drift region 24B is not located under the gate structure 32 in the vertical direction D3, and the high-voltage semiconductor device 102 may be regarded as an asymmetric DDDMOS structure, but not limited thereto. Additionally, in the high-voltage semiconductor device 102, the first source/drain doped region 26A may be a drain region and the second source/drain doped region 26B may be a source region, and a distance DS1 between the gate contact structure CT3 and the first drift region 24A in the horizontal direction D1 may be different from a distance DS2 between the gate contact structure CT3 and the second drift region 24B in the horizontal direction D1 for adjusting the influence of the gate contact structure CT3 on the electric field distribution. For example, the distance DS1 between the gate contact structure CT3 and the first drift region 24A in the horizontal direction D3 may be less than the distance DS2 between the gate contact structure CT3 and the second drift region 24B in the horizontal direction D1 for enhancing the influence of the gate contact structure CT3 on the electric field distribution in the first drift region 24A and/or in the first source/drain doped region 26A during the operation of the high-voltage semiconductor device 102, but not limited thereto. In addition, the distance between the gate contact structure CT3 and the first source/drain contact structure CT1 in the horizontal direction D1 may be substantially equal to the distance between the gate contact structure CT3 and the second source/drain contact structure CT2 in the horizontal direction D1, but not limited thereto.

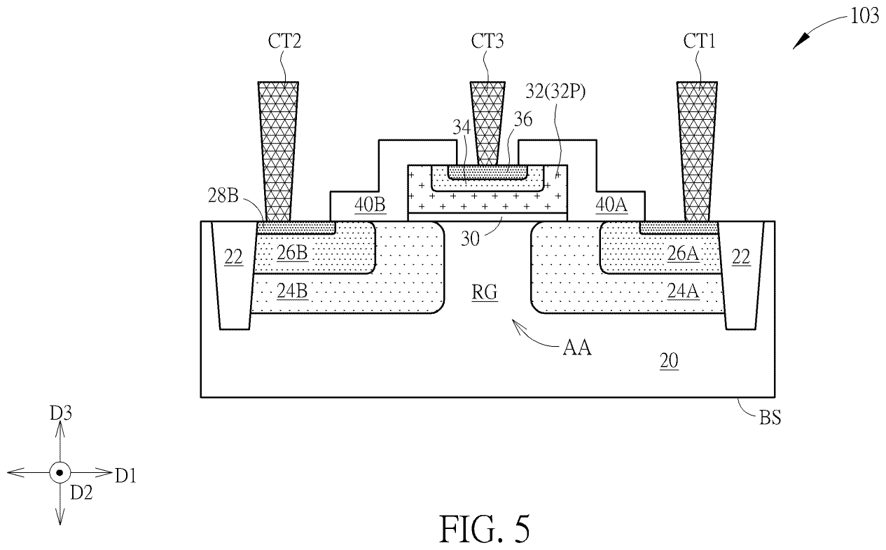

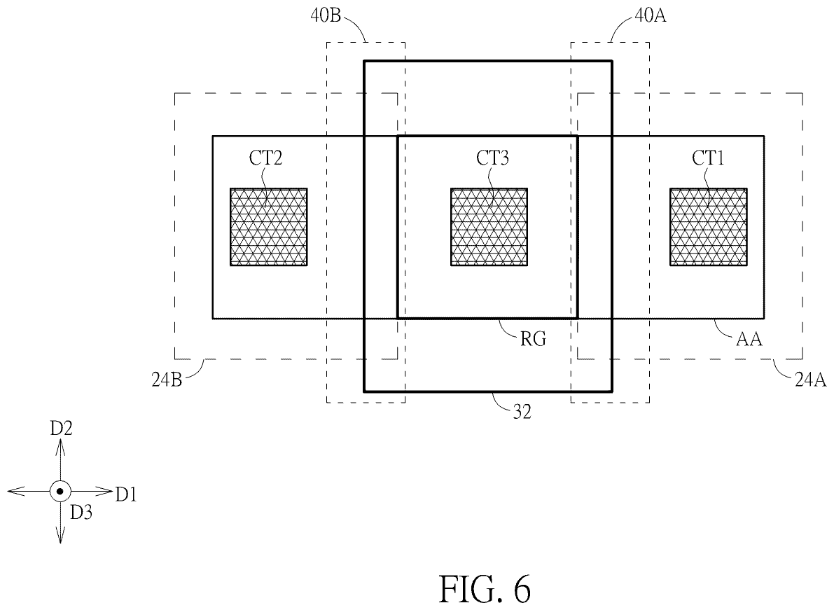

Please refer to FIG. 5 and FIG. 6. FIG. 5 is a schematic drawing illustrating a high-voltage semiconductor device 103 according to a third embodiment of the present invention, and FIG. 6 is a schematic drawing illustrating layout design of the high-voltage semiconductor device in this embodiment. In some embodiments, FIG. 6 may be regarded as a top view schematic drawing of the high-voltage semiconductor device 103, and some components are not illustrated in FIG. 6. As shown in FIG. 5 and FIG. 6, the high-voltage semiconductor device 103 may further include a first blocking pattern 40A and a second blocking pattern 40B. The first blocking pattern 40A may be disposed partly on the gate structure 32 in the vertical direction D3 and partly on the first drift region 24A and the first source/drain doped region 26A in the vertical direction D3, and the second blocking pattern 40B may be disposed partly on the gate structure 32 in the vertical direction D3 and partly on the second drift region 24B and the second source/drain doped region 26B in the vertical direction D3. In some embodiments, the first blocking pattern 40A and the second blocking pattern 40B may be regarded as a blocking layer for keeping the self-aligned silicide layer from being formed in some areas, and the first blocking pattern 40A and the second blocking pattern 40B may respectively include a single layer or multiple layers of insulation materials, such as silicon oxide, silicon nitride, silicon oxynitride, or other suitable insulation materials. When the high-voltage semiconductor device 103 is viewed in the vertical direction D3 (such as the condition shown in FIG. 6, but not limited thereto), the gate contact structure CT3 may not overlap the first blocking pattern 40A and the second blocking pattern 40B, and the gate contact structure CT3 may be sandwiched between the first blocking pattern 40A and the second blocking pattern 40B in the horizontal direction D1. In some embodiments, the doped region 34 may be disposed in the gate structure 32, and at least a part of the silicide layer 36 may be disposed in the doped region 34. A portion of the gate structure 32 may be sandwich between the first blocking pattern 40A and the doped region 34 in the horizontal direction D1, another portion of the gate structure 32 may be sandwich between the second blocking pattern 40B and the doped region 34 in the horizontal direction D1, and a portion of the doped region 34 may be sandwiched between the silicide layer 36 and the gate structure 32 in the horizontal direction D1, but not limited thereto. It is worth noting that, the allocation of the doped region 34 and the silicide layer 36 in the gate structure 32 of this embodiment may also be applied to other embodiments of the present invention according to some design considerations, and the high-voltage semiconductor device 103 may be regarded as a symmetric offset-gate MOS structure, but not limited thereto.

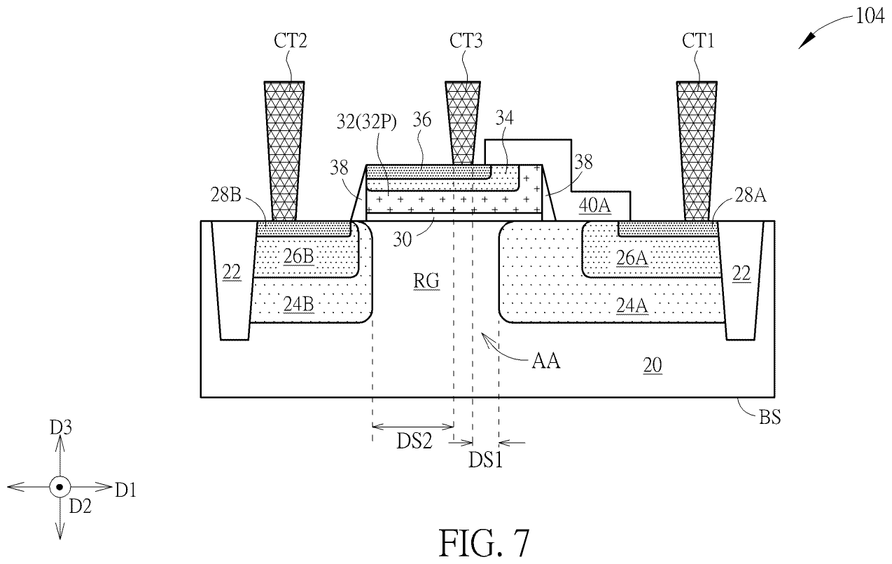

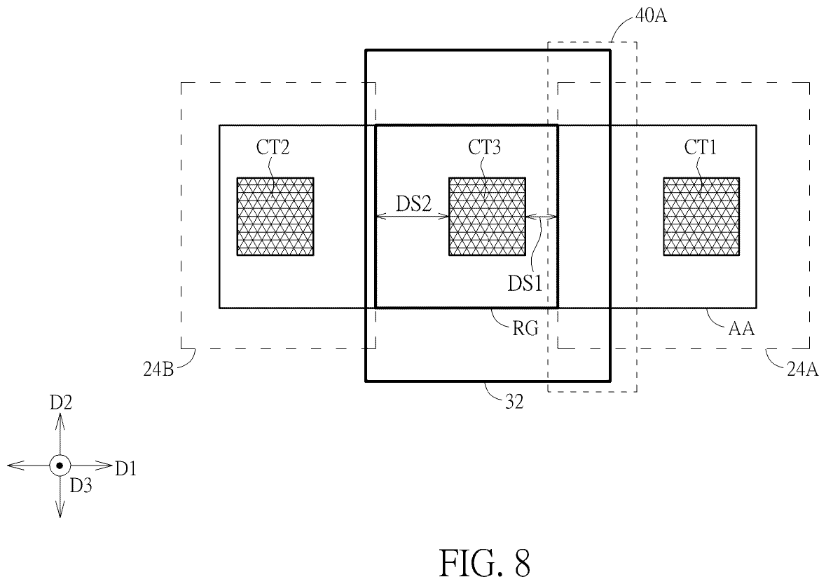

Please refer to FIG. 7 and FIG. 8. FIG. 7 is a schematic drawing illustrating a high-voltage semiconductor device 104 according to a fourth embodiment of the present invention, and FIG. 8 is a schematic drawing illustrating layout design of the high-voltage semiconductor device in this embodiment. In some embodiments, FIG. 8 may be regarded as a top view schematic drawing of the high-voltage semiconductor device 104, and some components are not illustrated in FIG. 8. As shown in FIG. 7 and FIG. 8, the high-voltage semiconductor device 104 may include the first blocking pattern 40A but does not include the second blocking pattern 40B in the third embodiment described above, and the high-voltage semiconductor device 104 may be regarded as an asymmetric offset-gate MOS structure, but not limited thereto. In the high-voltage semiconductor device 104, the first drift region 24A may be partly located under the gate structure 32 in the vertical direction D3, the first source/drain doped region 26A may be a drain region and the second source/drain doped region 26B may be a source region, and the distance DS1 between the gate contact structure CT3 and the first drift region 24A in the horizontal direction D1 may be less than the distance DS2 between the gate contact structure CT3 and the second drift region 24B in the horizontal direction D1.

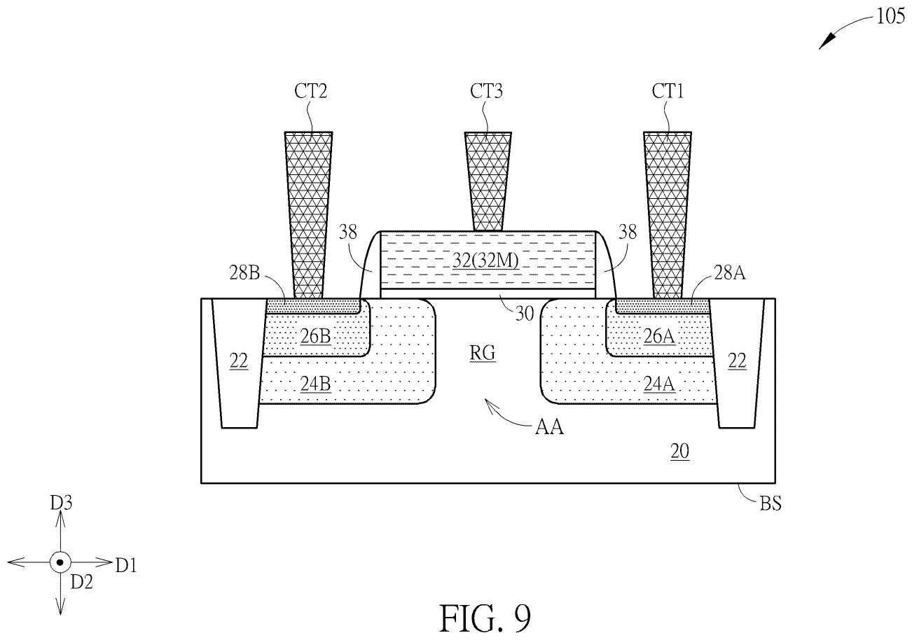

Please refer to FIG. 9. FIG. 9 is a schematic drawing illustrating a high-voltage semiconductor device 105 according to a fifth embodiment of the present invention. As shown in FIG. 9, in the high-voltage semiconductor device 105, the gate structure 32 may be a metal gate structure 32M, and the metal gate structure 32M may include a structure composed of a work function layer, a barrier layer, and a low electrical resistivity layer stacked with one another, but not limited thereto. When the gate structure 32 is the metal gate structure 32M, the gate contact structure CT3 may directly contact the metal gate structure 32M for being electrically connected with the metal gate structure 32M. It is worth noting that the metal gate structure 32M in this embodiment may also be applied to other embodiments of the present invention according to some design considerations.

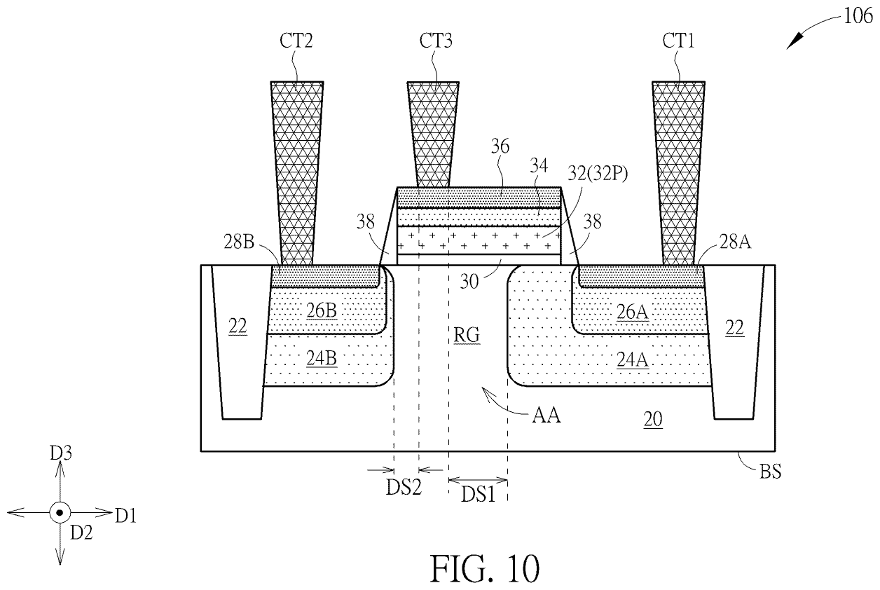

Please refer to FIG. 10. FIG. 10 is a schematic drawing illustrating a high-voltage semiconductor device 106 according to a sixth embodiment of the present invention. As shown in FIG. 10, in the high-voltage semiconductor device 106, the first drift region 24A may be partly located under the gate structure 32 in the vertical direction D3, the second drift region 24B may not be located under the gate structure 32 in the vertical direction D3, and the high-voltage semiconductor device 106 may be regarded as an asymmetric DDDMOS structure, but not limited thereto. Additionally, in the high-voltage semiconductor device 106, the first source/drain doped region 26A may be a drain region and the second source/drain doped region 26B may be a source region, and the distance DS1 between the gate contact structure CT3 and the first drift region 24A in the horizontal direction D1 may be greater than the distance DS2 between the gate contact structure CT3 and the second drift region 24B in the horizontal direction D1 for relatively reducing the influence of the gate contact structure CT3 on the electric field distribution in the first drift region 24A and/or in the first source/drain doped region 26A during the operation of the high-voltage semiconductor device 106, but not limited thereto. In addition, the distance between the gate contact structure CT3 and the first source/drain contact structure CT1 in the horizontal direction D1 may be greater than the distance between the gate contact structure CT3 and the second source/drain contact structure CT2 in the horizontal direction D1, but not limited thereto.

To summarize the above descriptions, in the high-voltage semiconductor device according to the present invention, by disposing the gate contact structure directly above the semiconductor region sandwiched between the two drift regions, there is no need to increase the surface area of the gate structure in the vertical direction in order to be connected with the gate contact structure. Therefore, the area occupied by the high-voltage semiconductor device may be relatively reduced, and the distribution density of the high-voltage semiconductor devices may be increased accordingly. In addition, the distances between the gate contact structure and the two drift regions may be modified according to the design requirements of different types of high-voltage semiconductor devices for further improving the operation performance of the high-voltage semiconductor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A high-voltage semiconductor device, comprising:
a semiconductor substrate;
a gate structure disposed on the semiconductor substrate;
a first drift region and a second drift region disposed in the semiconductor substrate, wherein a part of the first drift region and a part of the second drift region are located at two opposite sides of the gate structure in a horizontal direction, respectively, the first drift region is partly located under the gate structure in a vertical direction, and the semiconductor substrate comprises a semiconductor region sandwiched between the first drift region and the second drift region in the horizontal direction; and
a gate contact structure disposed on and electrically connected with the gate structure, wherein the gate contact structure is located directly above the semiconductor region in the vertical direction.

2. The high-voltage semiconductor device according to claim 1, wherein the gate contact structure does not overlap the first drift region or the gate contact structure does not overlap the second drift region when the high-voltage semiconductor device is viewed in the vertical direction.

3. The high-voltage semiconductor device according to claim 1, wherein the second drift region is partly located under the gate structure in the vertical direction.

4. The high-voltage semiconductor device according to claim 1, wherein a distance between the gate contact structure and the first drift region in the horizontal direction is different from a distance between the gate contact structure and the second drift region in the horizontal direction.

5. The high-voltage semiconductor device according to claim 4, wherein the distance between the gate contact structure and the first drift region in the horizontal direction is less than the distance between the gate contact structure and the second drift region in the horizontal direction.

6. The high-voltage semiconductor device according to claim 4, wherein the distance between the gate contact structure and the first drift region in the horizontal direction is greater than the distance between the gate contact structure and the second drift region in the horizontal direction.

7. The high-voltage semiconductor device according to claim 1, further comprising:
a first source/drain doped region and a second source/drain doped region, wherein the first source/drain doped region and the second source/drain doped region are disposed in the semiconductor substrate and located in the first drift region and the second drift region, respectively;
a first source/drain contact structure disposed on and electrically connected with the first source/drain doped region; and
a second source/drain contact structure disposed on and electrically connected with the second source/drain doped region.

8. The high-voltage semiconductor device according to claim 7, wherein a conductivity type of the first source/drain doped region and the second source/drain doped region is identical to a conductivity type of the first drift region and the second drift region.

9. The high-voltage semiconductor device according to claim 7, wherein the gate contact structure is sandwiched between the first source/drain contact structure and the second source/drain contact structure in the horizontal direction.

10. The high-voltage semiconductor device according to claim 1, further comprising:
a first blocking pattern disposed partly on the gate structure in the vertical direction and partly on the first drift region in the vertical direction, wherein the gate contact structure does not overlap the first blocking pattern when the high-voltage semiconductor device is viewed in the vertical direction.

11. The high-voltage semiconductor device according to claim 10, further comprising:
a second blocking pattern disposed partly on the gate structure in the vertical direction and partly on the second drift region in the vertical direction, wherein the gate structure does not overlap the second blocking pattern when the high-voltage semiconductor device is viewed in the vertical direction.

12. The high-voltage semiconductor device according to claim 11, wherein the gate contact structure is sandwiched between the first blocking pattern and the second blocking pattern in the horizontal direction.

13. The high-voltage semiconductor device according to claim 1, wherein the gate structure is a non-metallic gate structure.

14. The high-voltage semiconductor device according to claim 1, wherein the gate structure is a metal gate structure.

15. The high-voltage semiconductor device according to claim 1, wherein a part of the gate structure is sandwiched between the gate contact structure and the semiconductor region in the vertical direction.

16. The high-voltage semiconductor device according to claim 1, further comprising:
a doped region disposed in the gate structure, wherein a part of the doped region is sandwiched between the gate contact structure and the semiconductor region in the vertical direction.

17. The high-voltage semiconductor device according to claim 16, further comprising:
a silicide layer, wherein at least a part of the silicide layer is disposed in the doped region, and the gate contact structure is disposed above the silicide layer in the vertical direction.
